(19) United States
(12) Patent Application Publication
(10) Pub. No.: US 2024/0082956 A1
(43) Pub. Date: Mar. 14, 2024

(54) SUBSTRATE PROCESSING METHOD AND SUBSTRATE PROCESSING APPARATUS

(71) Applicant: Tokyo Electron Limited, Tokyo (JP)

(72) Inventors: Susumu HAYAKAWA, Kikuchi-gun, Kumamoto (JP); Yohei YAMASHITA, Kikuchi-gun, Kumamoto (JP); Yasutaka MIZOMOTO, Kikuchi-gun, Kumamoto (JP)

(21) Appl. No.: 18/262,201

(22) PCT Filed: Jan. 11, 2022
(86) PCT No.: PCT/JP2022/000579

§ 371 Date: Jul. 20, 2023

(30) Foreign Application Priority Data
Jan. 21, 2021 (JP) 2021-008295

(51) Int. Cl. B23K 26/352; B23K 26/082; H01L 21/304; H01L 21/683

(52) U.S. Cl. CPC B23K 26/352; B23K 26/082; H01L 21/304; H01L 21/6831

(57) ABSTRACT

A substrate processing method includes (A) to (C) to be described below. (A) A substrate having a first main surface and a second main surface opposite to the first main surface, and having unevenness on each of the first main surface and the second main surface is prepared. (B) Based on a measurement result of the unevenness of a first surface between the first main surface and the second main surface of the substrate, the first surface is planarized by radiating a laser beam to the first surface. (C) After planarizing the first surface of the substrate, a second surface of the substrate opposite to the first surface is planarized by grinding the second surface.

### TECHNICAL FIELD

The various aspects and embodiments described herein pertain generally to a substrate processing method and a substrate processing apparatus.

### BACKGROUND

Patent Document 1 describes a processing method for a semiconductor wafer. In this processing method, a chamfering process, a wrapping process, an etching process, and a mirror-surface polishing process are performed on the semiconductor wafer obtained by slicing a single-crystalline ingot.

### PRIOR ART DOCUMENT

Patent Document 1: Japanese Patent Laid-open Publication No. 2002-203823

### DISCLOSURE OF THE INVENTION

### Problems to be Solved by the Invention

Exemplary embodiments provide a technique of removing unevenness present on both surfaces of a substrate in a short time and planarizing both surfaces of the substrate in a short time.

### Means for Solving the Problems

In an exemplary embodiment, a substrate processing method includes (A) to (C) to be described below. (A) A substrate having a first main surface and a second main surface opposite to the first main surface, and having unevenness on each of the first main surface and the second main surface is prepared. (B) Based on a measurement result of the unevenness of a first surface between the first main surface and the second main surface of the substrate, the first surface is planarized by radiating a laser beam to the first surface. (C) After planarizing the first surface of the substrate, a second surface of the substrate opposite to the first surface is planarized by grinding the second surface.

### Effect of the Invention

According to the exemplary embodiment, it is possible to remove the unevenness present on both surfaces of the substrate in the short time, thus allowing both surfaces of the substrate to be planarized in the short time.

### BRIEF DESCRIPTION OF THE DRAWINGS

FIG. 1 is a flowchart illustrating a substrate processing method according to an exemplary embodiment.

FIG. 2 is a cross sectional view illustrating an example of a process S102 of FIG. 1.

FIG. 3 is a cross sectional view illustrating an example of a size of unevenness of a substrate.

FIG. 4 is a diagram illustrating an example of a process S107 of FIG. 1.

FIG. 5 is a diagram illustrating an example of a process S110 of FIG. 1.

FIG. 6 is a plan view illustrating a substrate processing apparatus according to the exemplary embodiment.

FIG. 7 is a plan view illustrating a substrate processing apparatus according to a first modification example.

FIG. 8 is a plan view illustrating a substrate processing apparatus according to a second modification example.

FIG. 9 is a flowchart illustrating an example of a processing performed by the substrate processing apparatus of FIG. 8.

FIG. 10 is a diagram illustrating an example of a laser processing module.

FIG. 11A is a diagram illustrating a first example of intensity distribution of a laser beam, and FIG. 11B is a diagram illustrating a second example of the intensity distribution of the laser beam.

FIG. 12A is a plan view illustrating a first example of a radiation point arrangement method, FIG. 12B is a plan view illustrating a second example of the radiation point arrangement method, and FIG. 12C is a plan view illustrating a third example of the radiation point arrangement method.

### DETAILED DESCRIPTION

Hereinafter, exemplary embodiments of the present disclosure will be described with reference to the accompanying drawings. In the various drawings, same or corresponding parts will be assigned same or corresponding reference numerals, and redundant description will be omitted. In the present specification, the X-axis direction, the Y-axis direction and the Z-axis direction are orthogonal to each other, and the X-axis and Y-axis directions are horizontal directions whereas the Z-axis direction is a vertical direction.

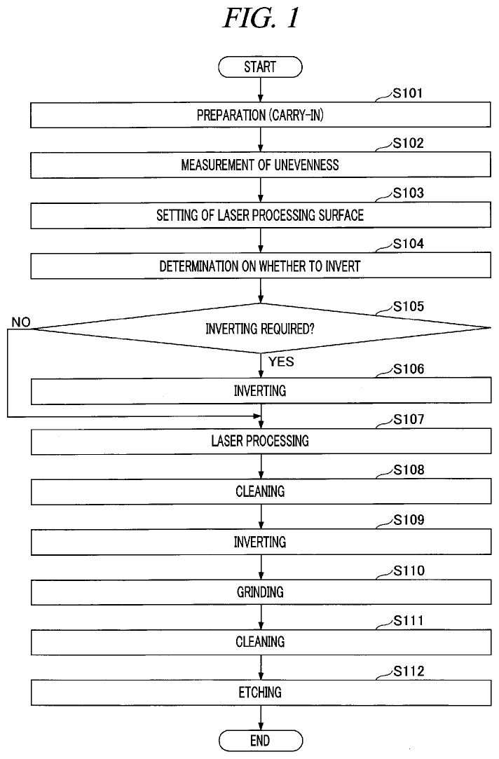

First, with reference to FIG. 1 to FIG. 5, a substrate processing method according to an exemplary embodiment will be described. The substrate processing method includes processes S101 to S112 shown in FIG. 1. Further, the substrate processing method may not include all of the processes S101 to S112 shown in FIG. 1 or may further include other processes not shown.

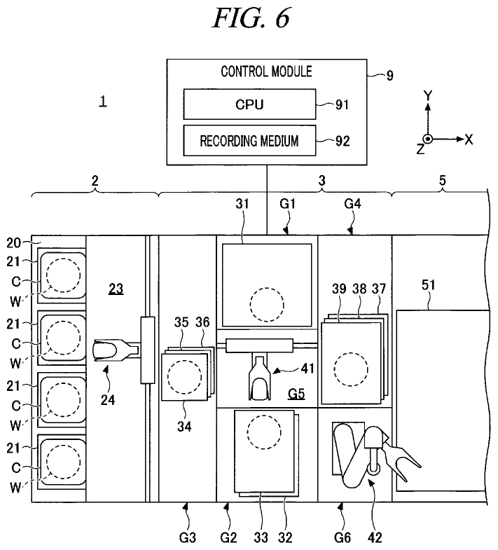

The process S101 includes preparing a substrate W. Preparing the substrate W includes, for example, carrying the substrate W into a substrate processing apparatus 1 (see FIG. 6, etc.) to be described later. The substrate W is carried into the substrate processing apparatus 1 while being accommodated in a cassette C.

The substrate W is a silicon wafer or a compound semiconductor wafer. Although not particularly limited, the compound semiconductor wafer may be, by way of example, a GaAs wafer, a SiC wafer, a GaN wafer or an InP wafer. The substrate W is a bare wafer.

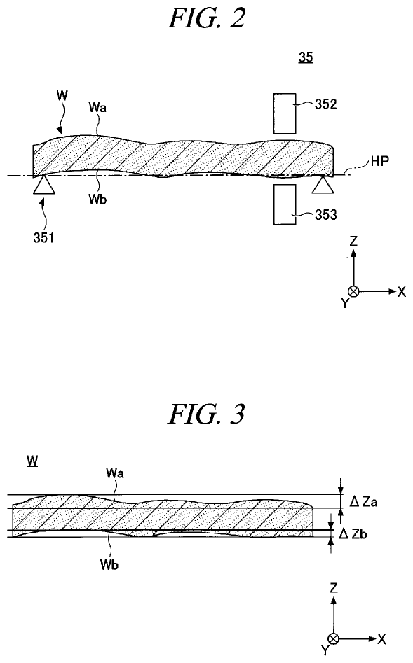

The substrate W has, for example, a disk shape. The substrate W may include a bevel at a periphery thereof. As shown in FIG. 2, the substrate W includes a first main surface Wa, and a second main surface Wb opposite to the first main surface Wa. The first main surface Wa and the second main surface Wb are formed by slicing a single-crystalline ingot. For this reason, the substrate W has unevenness on both the first main surface Wa and the second main surface Wb.

The process S102 includes measuring the unevenness of the substrate W, as shown in FIG. 2. The measurement of the unevenness is performed by using a unevenness measuring module 35. The unevenness measuring module 35 includes, for example, a holder 351 and measurement heads 352 and 353. The unevenness measuring module 35 may include either one of the measurement heads 352 and 353. If the substrate W is inverted, the unevenness on both surfaces of the substrate W can be measured with the single measurement head.

The holder 351 is configured to hold the substrate W in a natural state. The natural state is a state in which no external force (for example, an attracting force) other than the gravity and its drag force acts on the substrate W. The holder 351 includes, for example, a plurality of (e.g., three) pins. The substrate W is placed on the plurality of pins. Upper ends of the plurality of pins are disposed on same horizontal plane HP. The holder 351 holds the substrate W horizontally, allowing the first main surface Wa of the substrate W to face upwards.

The measurement head 352 is configured to measure a height distribution of a top surface (for example, the first main surface Wa) of the substrate W, for example. Meanwhile, the measurement head 353 is configured to measure a height distribution of a bottom surface (for example, the second main surface Wb) of the substrate W. A reference plane for height is, for example, the horizontal plane HP. Alternatively, the reference plane for height may be a crystal plane represented by a required Miller index or a plane inclined from the crystal plane by a required off angle.

The measurement head 352 (353) includes, for example, an infrared sensor, a laser displacement meter, a capacitance sensor, or the like. The height distribution is obtained by measuring the distance between the measurement head 352 (353) and the substrate W while moving the substrate W relative to the measurement head 352 (353) in a horizontal direction. Although the measurement head 352 (353) is of a non-contact type in the present exemplary embodiment, it may be of a contact type. The measurement head 352 (353) transmits the measurement data to a control module 9 (see FIG. 6, etc.).

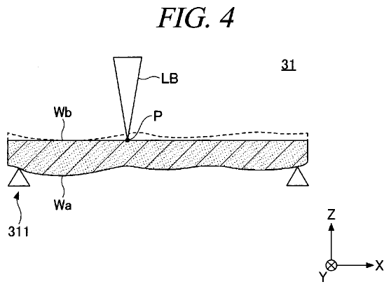

The process S103 includes setting, between the first main surface Wa and the second main surface Wb of the substrate W, the one having a smaller unevenness size as a first processing surface to be planarized with a laser beam. The process of planarizing the first processing surface with the laser beam will also be referred to as a laser processing or a first processing hereinafter. In the present exemplary embodiment, the first processing surface is the second main surface Wb, as shown in FIG. 4.

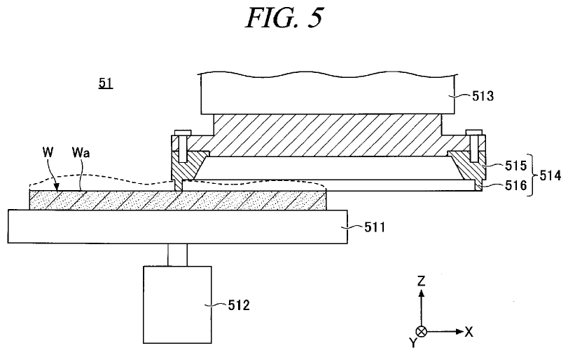

Further, the process S103 may include setting, between the first main surface Wa and the second main surface Wb of the substrate W, the one having a larger unevenness size as a second processing surface to be planarized with a grinding tool. The process of planarizing the second processing surface with the grinding tool will also be referred to as a grinding processing or a second processing hereinafter. In the present exemplary embodiment, the second processing surface is the first main surface Wa, as shown in FIG. 5.

By way of example, as depicted in FIG. 3, a size ΔZa of the unevenness of the first main surface Wa is represented by a maximum value of a height difference. Likewise, a size ΔZb of the unevenness of the second main surface Wb is represented by a maximum value of a height difference. Although the reference plane for height is the horizontal plane HP as stated above, it may be the crystal plane represented by the required Miller index or the plane inclined from the crystal plane by the required off angle. Although the sizes ΔZa and ΔZb are represented by the maximum values of the height difference in the present exemplary embodiment, they may be represented by volumes to be removed by the planarizing.

The processing speed of the first processing (laser processing) is lower than that of the second processing (grinding processing). In consideration of this, the control module 9 may set, between the first main surface Wa and the second main surface Wb, the one having the smaller unevenness size as the first processing surface and the other having the larger unevenness as the second processing surface, based on the measurement result of the unevenness of the first main surface Wa and the measurement result of the unevenness of the second main surface Wb. Therefore, a throughput can be improved.

When the sizes of the unevenness on the first main surface Wa and the second main surface Wb are the same, the control module 9 sets the surface facing upwards (for example, the first main surface Wa) as the first processing surface, and may set the surface facing downwards (for example, the second main surface Wb) as the second processing surface. The first processing (laser processing) is performed prior to the second processing (grinding processing). For this reason, if the surface facing upwards is set as the first processing surface, a process of inverting the substrate W can be omitted.

The process S104 includes determining whether to invert the substrate W based on the measurement result of the unevenness of the first main surface Wa and the measurement result of the unevenness of the second main surface Wb. For example, the control module may determine to invert the substrate W when the first processing surface faces downwards, and may determine not to invert the substrate W when the first processing surface faces upwards.

When it is necessary to invert the substrate W (process S105, YES), the control module 9 controls an inverting module 38 (see FIG. 6) or the like to invert the substrate W upside down (process S106). Meanwhile, when it is not necessary to invert the substrate W (process S105, NO), the control module 9 does not perform the process S106 but performs a process S107.

The process S107 includes planarizing the first processing surface by radiating a laser beam to the first processing surface based on the measurement result of the unevenness of one (specifically, the first processing surface) of the first main surface Wa and the second main surface Wb of the substrate W. As shown in FIG. 4, a laser beam LB is radiated to the top surface of the substrate W. For the reason, the substrate W is held horizontally with the first processing surface thereof facing upwards.

The first processing (laser processing) is performed by using a laser processing module 31. The laser processing module 31 is configured to radiate the laser beam LB to the first processing surface, as illustrated in FIG. 4. A surface layer of the first processing surface absorbs the laser beam LB, and is removed by being scattered after changing from a solid state to a gas state or by being scattered in the solid state.

The laser processing module 31 moves a position of a radiation point P of the laser beam LB within the plane of the first processing surface to planarize the first processing surface. The laser beam LB may be radiated to the entire first processing surface, or only to a part of the first processing surface. Even in the latter case, the first processing surface can still be planarized.

The depth of the surface layer removed by the radiation of the laser beam LB is controlled by a total radiation amount (unit: J), which is the product of an output of the laser beam LB (unit: W) and a radiation time. The larger the total radiation amount is, the deeper the depth of the surface layer to be removed may be. Since the first processing surface has the unevenness, the depth of the surface layer to be removed is different depending on a position in the surface of the first processing surface.

The control module 9 controls the total radiation amount of the laser beam LB per unit area of the first processing surface based on the measurement result of the unevenness measuring module 35. Since the first processing surface has the unevenness, the control module 9 changes the total radiation amount depending on the position in the surface of the first processing surface.

The control of the total radiation amount includes at least one selected from a control of the output of the light source 31b and a control of the radiation time. The control of the radiation time includes, for example, a control of the number of times of radiation. The larger the number of times of radiation is, the longer the radiation time and the deeper the depth of the surface layer to be removed may be. Since the depth of the surface layer to be removed is proportional to the number of times of radiation, it is easy to manage the depth of the surface layer to be removed.

The laser processing module 31 is equipped with a holder 311 configured to hold the substrate W. The holder 311 holds the substrate W in the natural state. The holder 311 includes a plurality of (for example, three) pins, for example. The substrate W is placed on the plurality of pins. Upper ends of the plurality of pins lie on the same horizontal plane. The holder 311 holds the substrate W horizontally, allowing the first processing surface of the substrate W to face upwards.

Unlike the process S102 (measurement of unevenness), the process S107 (laser processing) may be performed in the state that the substrate W is attracted to a horizontal attraction surface of a vacuum chuck. This is because the depth of the surface layer removed by the laser beam LB is determined by the total radiation amount. Further, if the substrate W is attracted, displacement of the substrate W can be suppressed.

Further, the process S107 may include imprinting identification information for identifying the substrate W on the first processing surface of the substrate W with the laser beam LB. The identification information is imprinted in the form of a letter (including a number), a one-dimensional code, or a two-dimensional code.

A process S108 includes cleaning the first processing surface after planarizing the first processing surface and before planarizing the second processing surface of the substrate W. The cleaning of the first processing surface includes, for example, at least one selected from scrub-cleaning and acid-cleaning. Debris scattered from the radiation point P of the laser beam LB to adhere to the first processing surface can be removed by the cleaning. The process S108 may include cleaning both of the first processing surface and the second processing surface. Further, if the removal of the debris is not necessary, the process S108 is omitted.

A process S109 includes inverting the substrate W. The process S109 includes inverting the substrate W upside down, thus allowing the first processing surface of the substrate W to face down and the second processing surface of the substrate W to face up, for example.

A process S110 includes, after planarizing the first processing surface of the substrate W, grinding the second processing surface of the substrate W opposite to the first processing surface to planarize the second processing surface. Since the second processing surface is not laser-processed before being subjected to the grinding, it has unevenness.

The planarization of the second processing surface is performed by using a grinding module 51, as shown in FIG. 5. The grinding module 51 includes a holder 511, a holder driving unit 512, and a tool driving unit 513.

The holder 511 is configured to hold the substrate W by attracting the first processing surface of the substrate W. The holder 511 is, for example, a vacuum chuck, and holds the substrate W horizontally by vacuum-attracting the first processing surface of the substrate W, allowing the second processing surface of the substrate W to face upwards. Alternatively, the holder 511 may be an electrostatic chuck.

The holder driving unit 512 is configured to rotate the holder 511 to rotate the substrate W held by the holder 511. The holder driving unit 512 includes, for example, a rotational motor and a transmission mechanism configured to transmit a rotational driving force of the rotational motor to the holder 511.

Meanwhile, the tool driving unit 513 is configured to drive a grinding tool 514 brought into contact with the second processing surface of the substrate W in the state that the substrate W is held by the holder 511. The grinding tool 514 includes, by way of example, a disk-shaped grinding wheel 515, and a plurality of whetstones 516 arranged in a ring shape on a bottom surface of the grinding wheel 515.

For example, the tool driving unit 513 includes a rotational motor, and a transmission mechanism configured to transmit a rotational driving force of the rotational motor to the grinding tool 514. The tool driving unit 513 may further include an elevating mechanism configured to move the grinding tool 514 up and down.

A process S111 includes, after planarizing the second processing surface of the substrate W, cleaning the second processing surface. The cleaning of the second processing surface includes, for example, scrub-cleaning. Grinding debris adhering to the second processing surface can be removed by the cleaning. The process S111 may include cleaning both of the first processing surface and the second processing surface.

A process S112 includes, after cleaning the second processing surface of the substrate W, etching the second processing surface. A damage caused during the grinding can be removed by etching the second processing surface. Further, surface roughness of the second processing surface can be reduced by etching the second processing surface.

As described above, the substrate processing method according to the present exemplary embodiment includes planarizing the first processing surface of the substrate W with the laser beam LB and, then, planarizing the second processing surface of the substrate W with the grinding tool 514. By grinding the second processing surface parallel to the previously planarized first processing surface, the second processing surface can be planarized.

If the first processing surface is attracted to the attraction surface of the holder 511 in the state that it has the unevenness, the first processing surface is planarized, conforming to the attraction surface. In this state, the second processing surface is ground parallel to the first processing surface. In this case, when the attraction of the substrate W by the holder 511 is released, the first processing surface returns to the state in which it has the unevenness, and, besides, the same unevenness as that of the first processing surface is formed on the second processing surface.

According to the present exemplary embodiment, by grinding the second processing surface parallel to the first processing surface planarized in advance, the second processing surface can be planarized. Further, as compared to a case where both surfaces of the substrate W are planarized with a laser beam, the unevenness existing on both surfaces of the substrate W can be removed in a short time, so that both surfaces of the substrate W can be planarized in a short time. This is because the laser processing has a slower processing speed than the grinding processing. As for the reason for not grinding both surfaces of the substrate W with the grinding tool 514, the grinding is a technique of making one surface of the substrate W parallel to the opposite surface, and the planarization does not proceed when both surfaces of the substrate W have unevenness.

Furthermore, according to the present exemplary embodiment, substrates W can be planarized one by one, and processing conditions can be changed for each of the substrates W. Therefore, as compared to a case where a plurality of substrates W having different unevenness are simultaneously planarized under the same processing conditions, both surfaces of the substrates W can be planarized in a short time. In addition, by planarizing the substrates W one by one, it is easy to track the history of the processing conditions of the substrates W. Thus, it is easy to correct the processing conditions of the substrates W based on processing results of the substrates W. Moreover, by planarizing the substrates W one by one, the apparatus can be downsized as compared to the case where the plurality of substrates W are planarized at the same time.

Now, referring to FIG. 6, the substrate processing apparatus 1 according to the present exemplary embodiment will be described. The substrate processing apparatus 1 includes a carry-in/out station 2, a first processing station 3, a second processing station 5, and the control module 9. The carry-in/out station 2, the first processing station 3, and the second processing station 5 are arranged in this order from the negative X-axis side toward the positive X-axis side.

The carry-in/out station 2 is equipped with a placing table 20 and a transfer section 23. The placing table 20 includes a plurality of placing plates 21. The plurality of placing plates 21 are arranged in a row in the Y-axis direction. A cassette C is disposed on each of the plurality of placing plates 21. Each cassette C horizontally accommodates therein a multiple number of substrates W that are arranged at a certain interval therebetween in a vertical direction. Here, the number of the placing plates 21 and the number of the cassettes C are not particularly limited.

The transfer section 23 is disposed adjacent to the positive X-axis side of the placing table 20 and adjacent to the negative X-axis side of the first processing station 3. The transfer section 23 is equipped with a transfer device 24 configured to transfer the substrate W. The transfer device 24 includes a transfer arm configured to hold the substrate W. The transfer arm is configured to be movable in horizontal directions (both X-axis direction and Y-axis direction) and a vertical direction and pivotable around a vertical axis. The transfer device 24 transfers the substrate W between the cassette C on the placing table 20 and the first processing station 3.

The first processing station 3 includes a first processing block G1, a second processing block G2, a third processing block G3, a fourth processing block G4, a first transfer section G5, and a second transfer section G6. The first transfer section G5 is provided in an area surrounded by the first processing block G1, the second processing block G2, the third processing block G3, and the fourth processing block G4 on four sides thereof. The second transfer section G6 is provided in an area surrounded by the second processing block G2, the fourth processing block G4, and the second processing station 5 on three sides thereof.

A first transfer device 41 configured to transfer the substrate W is disposed in the first transfer section G5. The first transfer device 41 includes a transfer arm configured to hold the substrate W. The transfer arm is configured to be movable in horizontal directions (both X-axis direction and Y-axis direction) and a vertical direction and pivotable around a vertical axis. The first transfer device 41 transfers the substrate W between the first processing block G1, the second processing block G2, the third processing block G3, and the fourth processing block G4.

A second transfer device 42 configured to transfer the substrate W is disposed in the second transfer section G6. The second transfer device 42 includes an attraction pad configured to attract the substrate W. The attraction pad is configured to be movable in horizontal directions (both X-axis direction and Y-axis direction) and a vertical direction and pivotable around a vertical axis. The second transfer device 42 transfers the substrate W between the second processing block G2, the fourth processing block G4, and the second processing station 5.

The first processing block G1 is disposed on the positive Y-axis side of the first transfer section G5. The first processing block G1 is equipped with the laser processing module 31, for example. The laser processing module 31 radiates the laser beam to the first processing surface of the substrate W to planarize the first processing surface.

The second processing block G2 is disposed on the negative Y-axis side of the first transfer section G5. The second processing block G2 includes, by way of example, a cleaning module 32 and an etching module 33. The cleaning module 32 is configured to clean the substrate W after being ground. The etching module 33 is configured to etch the substrate W after being ground. Although the etching module 33 etches the second processing surface of the substrate W in the present exemplary embodiment, it may etch the first processing surface of the substrate W. The etching module 33 for the second processing surface and the etching module 33 for the first processing surface may be provided separately. The cleaning module 32 and the etching module 33 are stacked on top of each other. The order of stacking is not limited to the example shown in FIG. 6.

The third processing block G3 is disposed on the negative X-axis side of the first transfer section G5. The third processing block G3 is equipped with, for example, a transition module 34, the unevenness measuring module 35, and an inverting module 36. The transition module 34 is configured to deliver the substrate W between the transfer device 24 of the carry-in/out station 2 and the first transfer device 41 of the first processing station 3. The unevenness measuring module 35 measures the unevenness of the first main surface Wa and the second main surface Wb of the substrate W. The inverting module 36 is configured to invert the substrate W. The transition module 34, the unevenness measuring module 35, and the inverting module 36 are stacked on top of each other. The order of stacking is not limited to the example shown in FIG. 6.

Further, when it is previously determined which of the first main surface Wa and the second main surface Wb is the first processing surface (laser processing surface), the unevenness measuring module 35 may measure the unevenness of only the first processing surface. For example, when the top surface of the substrate W is determined as the first processing surface, the unevenness measuring module 35 may measure the unevenness of only the top surface of the substrate.

The fourth processing block G4 is disposed on the positive X-axis side of the first transfer section G5. The fourth processing block G4 is equipped with, for example, a cleaning module 37, the inverting module 38, and an alignment module 39. The cleaning module 37 is configured to clean the substrate W after being subjected to the laser processing and before being subjected to the grinding. The inverting module 38 inverts the substrate W. The alignment module 39 is configured to detect a center of the substrate W. Also, the alignment module 39 detects a notch of the substrate W. The cleaning module 37, the inverting module 38, and the alignment module 39 are stacked on top of each other. The order of stacking is not limited to the example shown in FIG. 6.

In addition, the configuration of the first processing station 3 is not particularly limited as long as it has the laser processing module 31. The types, the layout and the number of the modules constituting the first processing station 3 are not limited to the example shown in FIG. 6.

The second processing station 5 has the grinding module 51, for example. The grinding module 51 grinds the second processing surface of the substrate W to planarize the second processing surface.

The control module 9 is, for example, a computer, and includes a CPU (Central Processing Unit) 91 and a recording medium 92 such as a memory. The recording medium 92 stores therein a program for controlling various kinds of processings performed in the substrate processing apparatus 1. The control module 9 controls an operation of the substrate processing apparatus 1 by causing the CPU 91 to execute the program stored in the recording medium 92.

Now, referring back to FIG. 1, an operation of the substrate processing apparatus 1 according to the present exemplary embodiment will be described. The processes S101 to S112 shown in FIG. 1 are performed under the control of the control module 9.

First, an external transfer device carries the substrate W into the carry-in/out station 2 of the substrate processing apparatus 1 (process S101). The cassette C accommodating the substrate W therein is placed on the placing table 20. Next, the transfer device 24 takes out the substrate W from the cassette C on the placing table 20 and transfers it to the transition module 34. Then, the first transfer device 41 of the first processing station 3 receives the substrate W from the transition module 34 and transfers it to the unevenness measuring module 35.

Next, the unevenness measuring module 35 measures the unevenness of the first main surface Wa and the second main surface Wb of the substrate W (process S102). The unevenness measuring module 35 transmits the measurement data to control module 9.

Subsequently, the control module 9 sets, between the first main surface Wa and the second main surface Wb of the substrate W, the one having the smaller unevenness size as the first processing surface (laser processing surface) (process S103). Further, the control module 9 determines whether or not to invert the substrate W (process S104).

When it is necessary to invert the substrate W (process S105, YES), the first transfer device 41 receives the substrate W from the unevenness measuring module 35 and transfers it to the inverting module 36. Next, the inverting module 36 inverts the substrate W upside down (process S106). Thereafter, the first transfer device 41 receives the substrate W from the inverting module 36 and transfers it to the laser processing module 31.

Meanwhile, when it is not necessary to invert the substrate W (process S105, NO), the first transfer device 41 receives the substrate W from the unevenness measuring module 35, and transfers it to the laser processing module 31.

Subsequently, the laser processing module 31 radiates the laser beam to the first processing surface based on the measurement result of the unevenness of the first processing surface of the substrate W to planarize the first processing surface (process S107)). Thereafter, the first transfer device 41 receives the substrate W from the laser processing module 31 and transfers it to the cleaning module 37.

Afterwards, the cleaning module 37 cleans the first processing surface of the substrate W (process S108). The cleaning module 37 may clean the second processing surface of the substrate W as well. Thereafter, the first transfer device 41 receives the substrate W from the cleaning module 37, and transfers it to the inverting module 38.

Next, the inverting module 38 inverts the substrate W upside down (process S109). Then, the first transfer device 41 receives the substrate W from the inverting module 38, and transfers it to the alignment module 39.

Subsequently, the alignment module 39 detects the center of the substrate W. The center of the substrate W and a rotation center line of the holder 511 of the grinding module 51 can be aligned. The alignment module 39 may detect the notch of the substrate W. In a rotating coordinate system that is rotated along with the holder 511, the crystalline orientation of the substrate W can be aligned to a required direction. The second transfer device 42 receives the substrate W from the alignment module 39 and transfers it to the grinding module 51 of the second processing station 5.

Then, the grinding module 51 grinds the second processing surface of the substrate W to planarize the second processing surface (process S110). Thereafter, the second transfer device 42 receives the substrate W from the grinding module 51, and transfers it to the cleaning module 32.

Next, the cleaning module 32 cleans the second processing surface of the substrate W (process S111). The cleaning module 32 may clean the first processing surface of the substrate W as well. Thereafter, the first transfer device 41 receives the substrate W from the cleaning module 32, and transfers it to the etching module 33.

Afterwards, the etching module 33 etches the second processing surface of the substrate W (process S112). The etching module 33 may etch the first processing surface of the substrate W as well. Thereafter, the first transfer device 41 receives the substrate W from the etching module 33, and transfers it to the transition module 34.

The etching of the first processing surface may be performed after the etching of the second processing surface. In this case, the inverting module 38 may invert the substrate W after the etching of the second processing surface and before the etching of the first processing surface.

The etching of the first processing surface may be performed before the etching of the second processing surface. The etching of the first processing surface may be performed at the same time as the etching of the second processing surface, and an etching liquid may be simultaneously supplied to both the top and bottom surfaces of the substrate W that is held horizontally.

Here, however, if the etching liquid is supplied from below the substrate W, non-uniformity in etching may easily occur, as compared to a case where the etching liquid is supplied from above the substrate W, raising a risk that uniformity of the thickness of the substrate W may be deteriorated.

When etching both the first processing surface and the second processing surface, it is desirable to turn the first processing surface and the second processing surface to face upwards in sequence and to supply the etching liquid to the surface facing upwards. The uniformity of the thickness of the substrate W can be improved.

The main purpose of etching the second processing surface is to improve the uniformity of the thickness of the entire surface of the substrate and remove a scratch mark caused by the grinding processing. When there is no scratch mark from the grinding processing, the main purpose of etching the second processing surface is to improve the uniformity of the thickness of the entire surface of the substrate.

The purpose of etching the first processing surface is to remove a contaminant adhering to the first processing surface in the grinding processing and remove a scratch mark caused by the laser processing. If there is no scratch mark from the laser processing, the main purpose of etching the first processing surface is to remove the contaminant. In particular, etching the first processing surface is effective in removing the contaminant including a metal component that are difficult to remove by the cleaning.

Next, the transfer device 24 of the carry-in/out station 2 receives the substrate W from the transition module 34, and transfers it to the cassette C on the placing table 20. The substrate W is taken out of the substrate processing apparatus 1 while being accommodated in the cassette C. Thus, the processing of the substrate W is ended.

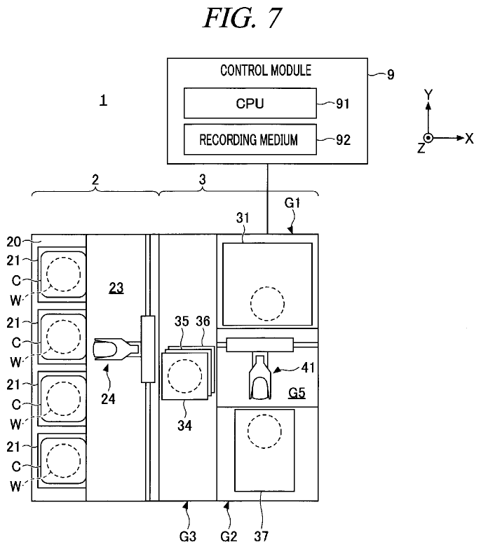

Now, referring to FIG. 7, a substrate processing apparatus 1 according to a first modification example will be described. The substrate processing apparatus 1 according to the present modification example performs the processes S101 to S109 among the processes S101 to S112 shown in FIG. 1. Further, the process S109 may be performed by a substrate processing apparatus 1 according to a second modification example described later. The following description will focus on differences between the present modification example and the above-described exemplary embodiment.

The substrate processing apparatus 1 is equipped with the carry-in/out station 2, the processing station 3, and the control module 9. The carry-in/out station 2 and the processing station 3 are arranged in this order from the negative X-axis side toward the positive X-axis side.

The processing station 3 is equipped with the first processing block G1, the second processing block G2, the third processing block G3, and a transfer section G5. The transfer section G5 is provided in an area surrounded by the first processing block G1, the second processing block G2, and the third processing block G3 on three sides thereof.

The transfer device 41 configured to transfer the substrate W is provided in the transfer section G5. The transfer device 41 transfers the substrate W between the first processing block G1, the second processing block G2, and the third processing block G3.

The first processing block G1 is disposed on the positive Y-axis side of the transfer section G5. The first processing block G1 is equipped with, for example, the laser processing module 31.

The second processing block G2 is disposed on the negative Y-axis side of the transfer section G5. The second processing block G2 is equipped with, for example, the cleaning module 37. The cleaning module 37 cleans the substrate W after being subjected to the laser processing and before being subjected to the grinding processing.

The third processing block G3 is disposed on the negative X-axis side of the transfer section G5. The third processing block G3 is equipped with, for example, the transition module 34, the unevenness measuring module 35, and the inverting module 36.

Now, referring back to FIG. 1, an operation of the substrate processing apparatus 1 according to the first modification example will be described. Among the processes S101 to S112 shown in FIG. 1, the processes S101 to S109 are performed under the control of the control module 9.

Description of the processes S101 to S108 will be omitted as it is the same as that of the above-described exemplary embodiment. After the process S108, the transfer device 41 receives the substrate W from the cleaning module 37, and transfers it to the inverting module 36.

Then, the inverting module 36 inverts the substrate W upside down (process S109). Thereafter, the transfer device 41 receives the substrate W from the inverting module 36, and transfers it to the transition module 34.

Further, the substrate processing apparatus 1 does not need to perform the process S109 as mentioned above. In this case, after the process S108, the transfer device 41 receives the substrate W from the cleaning module 37, and transfers it to the transition module 34.

Subsequently, the transfer device 24 of the carry-in/out station 2 receives the substrate W from the transition module 34, and transfers it to the cassette C on the placing table 20. The substrate W is taken out of the substrate processing apparatus 1 while being accommodated in the cassette C. Thus, the processing of the substrate W is ended.

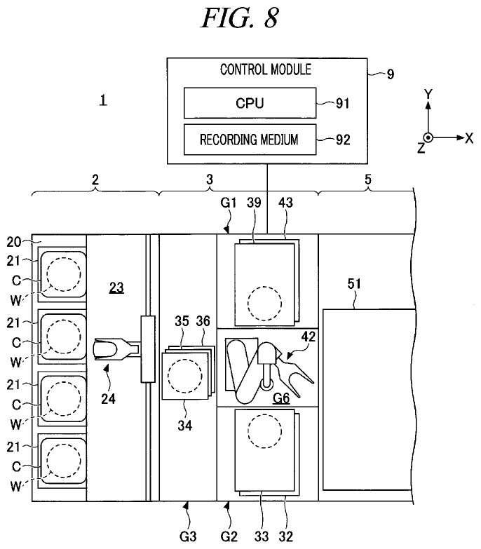

Now, with reference to FIG. 8, a substrate processing apparatus 1 according to a second modification example will be described. The substrate processing apparatus 1 according to the present modification example performs the processes S110 to S112 among the processes S101 to S112 shown in FIG. 1. Further, the substrate processing apparatus 1 may also perform the process S109. The following description will mainly focus on differences between the present modification example and the above-described exemplary embodiment.

The substrate processing apparatus 1 is equipped with the carry-in/out station 2, the first processing station 3, the second processing station 5, and the control module 9.

The first processing station 3 is equipped with the first processing block G1, the second processing block G2, the third processing block G3, and a transfer section G6. The transfer section G6 is provided in an area surrounded by the first processing block G1, the second processing block G2, and the third processing block G3 on three sides thereof.

The transfer device 42 configured to transfer the substrate W is provided in the transfer section G6. The transfer device 42 transfers the substrate W between the first processing block G1, the second processing block G2, the third processing block G3, and the second processing station 5.

The first processing block G1 is disposed on the positive Y-axis side of the first transfer section G5. The first processing block G1 includes, for example, a cleaning module 43 and the alignment module 39. The cleaning module 43 cleans the substrate W after being subjected to the laser processing and before being subjected to the grinding processing.

The second processing block G2 is disposed on the negative Y-axis side of the first transfer section G5. The second processing block G2 is equipped with, for example, the cleaning module 32 and the etching module 33. The cleaning module 32 cleans the substrate W after being subjected to the grinding processing. The etching module 33 etches the substrate W after being subjected to the grinding processing. Although the etching module 33 etches the second processing surface of the substrate W in the present modification example, it may etch the first processing surface of the substrate W. The etching module 33 for the second processing surface and the etching module 33 for the first processing surface may be provided separately.

The third processing block G3 is disposed on the negative X-axis side of the first transfer section G5. The third processing block G3 is equipped with, for example, the transition module 34, the unevenness measuring module 35, and the inverting module 36. The unevenness measuring module 35 measures unevenness of both the first main surface Wa and the second main surface Wb of the substrate W. The inverting module 36 inverts the substrate W.

The second processing station 5 has the grinding module 51, for example. The grinding module 51 grinds the second processing surface of the substrate W to planarize the second processing surface.

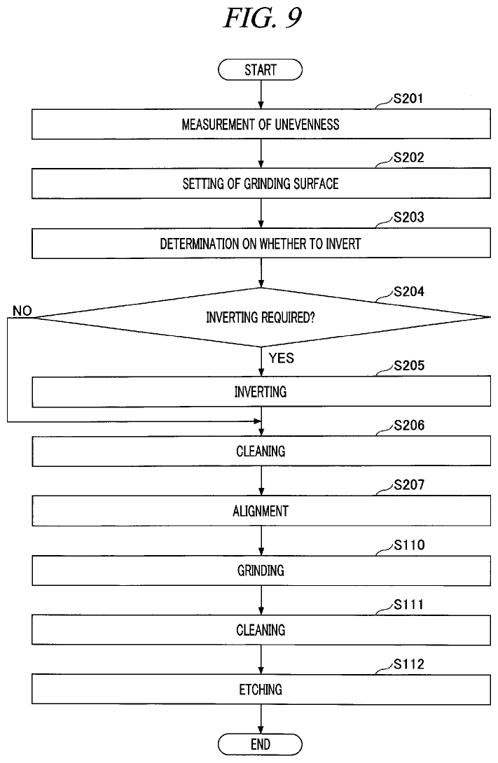

Now, an operation of the substrate processing apparatus 1 according to the second modification example will be explained with reference to FIG. 9. Processes S201 to S207 and the processes S110 to S112 shown in FIG. 9 are performed under the control of the control module 9.

First, an external transfer device carries the substrate W after being subjected to the laser processing into the carry-in/out station 2 of the substrate processing apparatus 1. The cassette C accommodating the substrate W after being subjected to the laser processing is placed on the placing table 20. Then, the transfer device 24 takes out the substrate W from the cassette C on the placing table 20, and transfers it to the transition module 34. Subsequently, the transfer device 42 of the first processing station 3 receives the substrate W from the transition module 34, and transfers it to the unevenness measuring module 35.

Next, the unevenness measuring module 35 measures the unevenness of both the first main surface Wa and the second main surface Wb of the substrate W (process S201). The unevenness measuring module 35 transmits the measurement data to control module 9.

Thereafter, the control module 9 sets, between the first main surface Wa and the second main surface Wb of the substrate W, the one having the larger unevenness as the second processing surface (grinding surface) (process S202). The unevenness with the small size indicates that the surface is finished with the laser processing to be thus planarized.

Subsequently, the control module 9 determines whether or not to invert the substrate W (process S203). For example, the control module determines to invert the substrate W when the second processing surface is facing downwards, and determines not to invert the substrate W when the second processing surface is facing upwards.

When it is necessary to invert the substrate W (process S204, YES), the transfer device 42 receives the substrate W from the unevenness measuring module 35, and transfers it to the inverting module 36. Then, the inverting module 36 inverts the substrate W upside down (process S205). Thereafter, the transfer device 42 receives the substrate W from the inverting module 36, and transfers it to the cleaning module 43.

Meanwhile, when it is not necessary to invert the substrate W (process S204, NO), the transfer device 42 receives the substrate W from the unevenness measuring module 35, and transfers it to the cleaning module 43.

Next, the cleaning module 43 cleans the substrate W (process S206). By way of example, the cleaning module 43 scrub-cleans the substrate W. Thereafter, the transfer device 42 receives the substrate W from the cleaning module 43, and transfers it to the alignment module 39. Further, when the substrate W is clean, the process S206 may not be performed.

Next, the alignment module 39 detects the center of the substrate W (process S207). The center of the substrate W and the rotation center line of the holder 511 of the grinding module 51 can be aligned. The alignment module 39 may detect the notch of the substrate W. In the rotating coordinate system that is rotated along with the holder 511, the crystalline orientation of the substrate W can be aligned to a required direction. The transfer device 42 receives the substrate W from the alignment module 39, and transfers it to the grinding module 51 of the second processing station 5.

Thereafter, the processes S110 to S112 are performed. Description of the processes S110 to S112 will be omitted here as it is the same as in the above-exemplary exemplary embodiment.

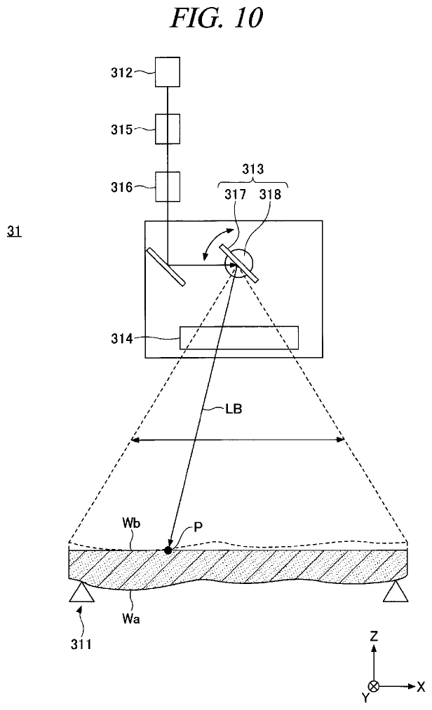

Subsequently, with reference to FIG. 10, an example of the laser processing module 31 will be explained. The laser processing module 31 includes the holder 311, a light source 312, and a Galvano scanner 313 as a moving unit. In addition, the laser processing module 31 is equipped with an fθ lens 314, a homogenizer 315, and an aperture 316.

The holder 311 holds the substrate W. For example, the holder 311 holds the substrate W horizontally from below, allowing the laser processing surface of the substrate W to face upwards. The holder 311 holds the substrate W in the natural state without attracting it. Alternatively, the holder 311 may be configured to attract the substrate W, and it may be a vacuum chuck or an electrostatic chuck.

The light source 312 is configured to oscillate the laser beam LB to be radiated to the top surface of the substrate W. The laser beam LB has a property that it is absorbed by the substrate W. When the substrate W is a silicon wafer, the laser beam LB is, for example, UV light. After the substrate W absorbs the laser beam LB, it scatters after changing its state from a solid state to a gas state, or scatters while remaining in the solid state. As a result, the top surface of the substrate W can be planarized. The laser beam LB may be radiated to the top surface of the substrate W so as to be condensed thereon. The radiation point P is a light-converging point where the power density becomes the highest, but it may not be the light-converging point.

The light source 312 is, for example, a pulsed laser. The radiation time per pulse is equal to or less than, e.g., 30 nsec. If the radiation time per pulse is 30 nsec or less, the substrate W can be radiated with the laser beam LB with the high power density in a short time, so that overheating of the substrate W can be suppressed. Therefore, deterioration of the substrate W due to the heat can be suppressed, and generation of a discoloration layer can be suppressed, for example. The radiation time per pulse is desirably 10 psec or less. If the radiation time per pulse is 10 psec or less, the deterioration of substrate W due to the heat can be suppressed even if the radiation point P is formed at the same place multiple times.

The Galvano scanner 313 is disposed above the substrate W held by the holder 311, for example. With the Galvano scanner 313, the position of the radiation point P of the laser beam LB on the top surface of the substrate W can be moved without moving the holder 311. Even in case that the holder 311 does not attract the substrate W, if the holder 311 is not moved, positional displacement of the substrate W with respect to the holder 311 does not occur. Therefore, the position of the radiation point P can be controlled with high precision.

The Galvano scanner 313 includes two sets of a Galvano mirror 317 and a galvanometer 318 (only one set is shown in FIG. 10). One galvanometer 318 rotates one galvanometer mirror 317 to displace the radiation point P in the X-axis direction. The other galvanometer 318 rotates the other galvanometer mirror 317 to displace the radiation point P in the Y-axis direction.

Further, although the moving unit of the present exemplary embodiment is configured by the Galvano scanner 313, the technique of the present disclosure is not limited thereto. The moving unit is not particularly limited as long as it is capable of moving the position of the radiation point P of the laser beam LB on the top surface of the substrate W in the state that the substrate W is held by the holder 311. By way of example, the moving unit may be configured to move the holder 311 in both the X-axis direction and the Y-axis direction, and may include a motor and a ball screw mechanism configured to convert a rotational motion of the motor into a linear motion of the holder 311. Moreover, the moving unit may have a mechanism configured to rotate the holder 311 around a vertical axis.

The fθ lens 314 is configured to form a focal plane perpendicular to the Z-axis direction. While the Galvano scanner 313 is moving the position of the radiation point P in the X-axis direction or the Y-axis direction, the fθ lens 314 maintains the position of the radiation point P in the Z-axis direction on the focal plane, and maintains the shape and the size of the radiation point P on the focal plane. As a result, as will be described later, rectangular radiation points P can be arranged two-dimensionally on the top surface of the substrate W regularly and without gaps. The height of the radiation point P is the height of the focal plane.

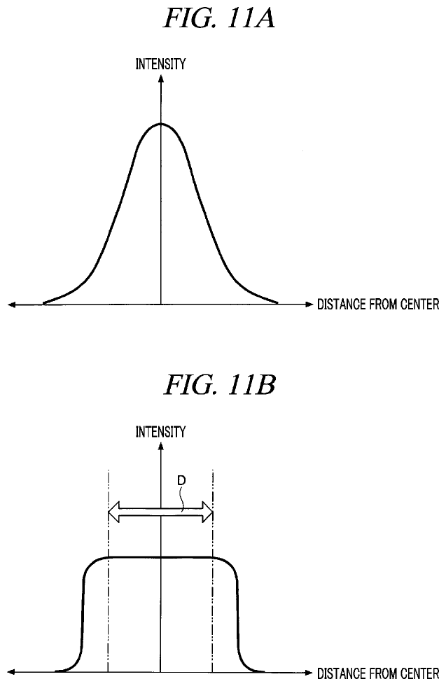

The homogenizer 315 is configured to convert the intensity distribution of the laser beam LB from the Gaussian distribution shown in FIG. 11A to the Top Hat distribution shown in FIG. 11B, and homogenizes the intensity distribution.

The aperture 316 is configured to form the cross-sectional shape of the laser beam LB into a rectangle. The rectangle includes a square as well as a rectangle. The aperture 316 is a light-shielding film having a rectangular opening. The opening allows the laser beam LB in the range indicated by an arrow D in FIG. 11B to pass therethrough, for example.

By the homogenizer 315 and the aperture 316, the rectangular radiation points P having the uniform intensity distribution can be formed. By arranging the radiation points P two-dimensionally and regularly without gaps as will be described later, the total radiation amount of the laser beam LB per unit area can be controlled with high precision.

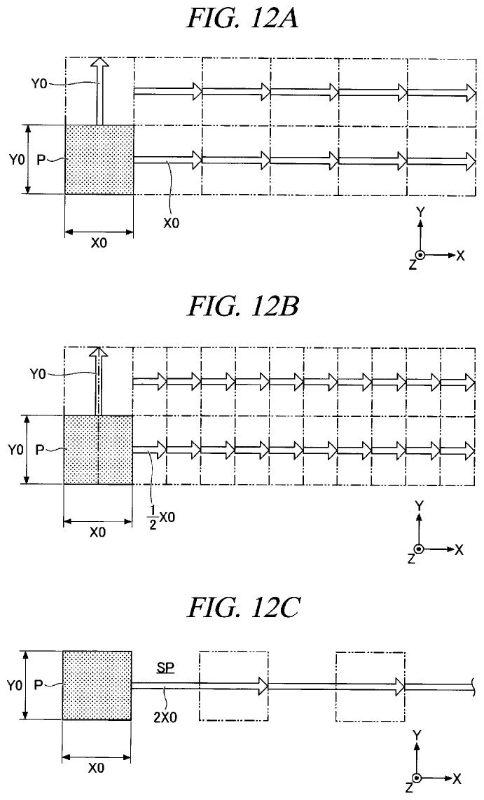

As shown in FIG. 12A, the radiation point P is a rectangle having a uniform intensity distribution, and two sides of this rectangle are parallel to the X-axis direction while the other two sides of the rectangle are parallel to the Y-axis direction. A dimension XO of the radiation point P in the X-axis direction may be the same as or different from a dimension Y0 of the radiation point P in the Y-axis direction. The same goes for FIG. 12B and FIG. 12C.

As shown in FIG. 12A, while oscillating the laser beam LB in a pulse shape, the control module 9 moves the radiation point P by XO in the X-axis direction during a pulse off-time, thus allowing the radiation points P to be arranged in a row over the entire X-axis side of the top surface of the substrate W without any gaps therebetween. Thereafter, while oscillating the laser beam LB in the pulse shape, the control module 9 repeats moving the radiation point P by Y0 in the Y-axis direction during the pulse off-time and moving the radiation point P by XO in the X-axis direction during the pulse off-time, thus allowing the radiation points P to be two-dimensionally arranged over the entire top surface of the substrate W without any gaps therebetween.

Alternatively, as shown in FIG. 12B, while oscillating the laser beam LB in a pulse shape, the control module 9 moves the radiation point P by half of XO in the X-axis direction during the pulse off-time, thus allowing the radiation points P to be arranged in a row over the entire X-axis side of the top surface of the substrate W while overlapping each other. Thereafter, while oscillating the laser beam LB in the pulse shape, the control module 9 repeats moving the radiation point P by Y0 in the Y-axis direction during the pulse off-time and moving the radiation point P by half of XO in the X-axis direction during the pulse-off time, thus allowing the radiation points P to be two-dimensionally arranged over the entire top surface of the substrate W without any gaps therebetween. Further, the control module 9 may move the radiation point P by half of Y0 instead of moving the radiation point P by Y0 in the Y-axis direction during the pulse off time.

Still alternatively, as shown in FIG. 12C, while oscillating the laser beam LB in a pulse shape, the control module 9 moves the radiation point P by twice as much as XO in the X-axis direction during the pulse off-time, thus allowing the radiation points P to be arranged in a row while forming gaps SP over the entire X-axis side of the top surface of the substrate W. Subsequently, while oscillating the laser beam LB in the pulse shape again, the control module 9 moves the radiation point P by twice as much as XO in the X-axis direction during the pulse off-time so as to fill the gaps SP with the radiation points P. Thereafter, while oscillating the laser beam LB in the pulse shape, the control module 9 repeats moving the radiation point P by Y0 in the Y-axis direction during the pulse off-time, moving the radiation point P by twice as much as XO in the X-axis direction during the pulse off-time, and moving the radiation point by twice as much as XO in the X-axis direction during the pulse off-time so as to fill the gaps SP with the radiation points P, thus allowing the radiation points P to be two-dimensionally arranged without any gaps therebetween.

So far, the exemplary embodiment of the substrate processing method and the substrate processing apparatus according to the present disclosure has been described. However, the present disclosure is not limited to the above-described exemplary embodiment or the like. Various changes, corrections, replacements, addition, deletion and combinations may be made within the scope of the claims, and all of these are included in the scope of the inventive concept of the present disclosure.

This application claims priority to Japanese Patent Application No. 2021-008295, field on Jan. 21, 2021, which application is hereby incorporated by reference in their entirety

### EXPLANATION OF CODES

1: Substrate processing apparatus
9: Control module (controller)
31: Laser processing module
311: Holder
312: Light source
313: Moving unit

1. A substrate processing method, comprising:
preparing a substrate having a first main surface and a second main surface opposite to the first main surface, and having unevenness on each of the first main surface and the second main surface;
planarizing, based on a measurement result of the unevenness of a first surface between the first main surface and the second main surface of the substrate, the first surface by radiating a laser beam to the first surface; and
planarizing, after planarizing the first surface of the substrate, a second surface of the substrate opposite to the first surface by grinding the second surface.

2. The substrate processing method of claim 1, further comprising:
setting, between the first main surface and the second main surface, one having a smaller unevenness size as the first surface to be planarized with the laser beam.

3. The substrate processing method of claim 1, further comprising:
determining whether or not to invert the substrate based on a measurement result of the unevenness of the first main surface and a measurement result of the unevenness of the second main surface.

4. The substrate processing method of claim 1, further comprising:
controlling a total radiation amount of the laser beam per unit area of the first surface of the substrate based on the measurement result of the unevenness of the first surface.

5. The substrate processing method of claim 4, further comprising:
controlling the total radiation amount of the laser beam per unit area of the first surface of the substrate by adjusting a number of times of radiation of the laser beam.

6. The substrate processing method of claim 1, further comprising:
using a pulse laser as a light source of the laser beam.

7. The substrate processing method of claim 1, further comprising:
holding the substrate in a natural state when the laser beam is radiated to the first surface of the substrate.

8. The substrate processing method of claim 7, further comprising:
using a Galvano scanner to move a position of a radiation point of the laser beam on the first surface of the substrate.

9. The substrate processing method of claim 1, further comprising:
cleaning, after planarizing the second surface of the substrate, the second surface; and
etching, after cleaning the second surface of the substrate, the second surface.

10. The substrate processing method of claim 1, further comprising:
etching the second surface of the substrate and etching the first surface of the substrate after planarizing the second surface.

11. A substrate processing apparatus, comprising:
a holder configured to hold a substrate which has a first main surface and a second main surface opposite to the first main surface and which has unevenness on each of the first main surface and the second main surface;
a light source configured to oscillate a laser beam to be radiated to a first surface between the first main surface and the second main surface of the substrate;
a moving unit configured to move a position of a radiation point of the laser beam on the first surface of the substrate in a state that the substrate is held by the holder; and
a controller configured to control, based on a measurement result of the unevenness of the first surface of the substrate, the light source and the moving unit to planarize the first surface.

12. The substrate processing apparatus of claim 11,
wherein the controller sets, between the first main surface and the second main surface, one having a smaller unevenness size as the first surface to be radiated with the laser beam.

13. The substrate processing apparatus of claim 11, further comprising:
an inverting unit configured to invert the substrate,
wherein the controller determines whether or not to invert the substrate based on a measurement result of the unevenness of the first main surface and a measurement result of the unevenness of the second main surface.

14. The substrate processing apparatus of claim 11,
wherein the controller controls a total radiation amount of the laser beam per unit area of the first surface of the substrate based on the measurement result of the unevenness of the first surface.

15. The substrate processing apparatus of claim 14,
wherein the controller controls the total radiation amount of the laser beam per unit area of the first surface of the substrate by adjusting a number of times of radiation of the laser beam.

16. The substrate processing apparatus of claim 11,
wherein the light source includes a pulse laser.

17. The substrate processing apparatus of claim 11,
wherein the holder holds the substrate in a natural state.

18. The substrate processing apparatus of claim 17,
wherein the moving unit includes a Galvano scanner.

19. The substrate processing apparatus of claim 11, further comprising:
a second holder configured to hold the substrate by attracting the first surface planarized by radiation of the laser beam; and
a tool driving unit configured to drive a grinding tool brought into contact with a second surface of the substrate opposite to the first surface in a state that the substrate is held by the second holder.

20. A substrate processing apparatus, comprising:
a holder configured to hold a substrate having a first main surface and a second main surface opposite to the first main surface by attracting a first surface between the first main surface and the second main surface, the first surface being planarized by radiation of a laser beam and a second surface opposite to the first surface having unevenness; and
a tool driving unit configured to drive a grinding tool brought into contact with the second surface of the substrate in a state that the substrate is held by the holder.
